(19) United States
(12) Patent Application Publication
(10) Pub. No.: US 2008/0309354 A1
(43) Pub. Date: Dec. 18, 2008

(54) METHOD AND APPARATUS FOR TESTING CHARACTERISTIC IMPEDANCE OF TRANSMISSION LINES

(75) Inventor: SHOU-KUO HSU, Tu-Cheng (TW)

Correspondence Address: PCE INDUSTRY, INC.;ATT. CHENG-JU CHIANG, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/963,873

(22) Filed: Dec. 24, 2007

(30) Foreign Application Priority Data
Jun. 15, 2007 (CN) 200710200828.1

(51) Int. Cl. G01R 27/02

(52) U.S. Cl. 324/705

(57) ABSTRACT

An apparatus for testing characteristic impedance of transmission lines includes a variable resistor, a first comparator, a second comparator, and a counter. One terminal of the variable resistor is coupled to a signal source, another terminal of the variable resistor is coupled to one terminal of a transmission line, and another terminal of the transmission line is idle. The one terminal of the transmission line is coupled to the input terminals of the first and second comparators. The output terminals of the first and second comparators are respectively coupled to input terminals of the counter. An output terminal of the counter is coupled to an adjusting terminal of the variable resistor, the counter adjusts the resistance of the variable resistor according to signals output from the first and second comparators.

### BACKGROUND

1. Field of the Invention

The present invention relates to a method and an apparatus for testing characteristic impedance of transmission lines.

2. Description of Related Art

Electronic equipment, including processors and related devices, frequently require transmission lines such as buses to provide high-speed connections for passing signals between circuit elements. To achieve this end, printed circuit boards (PCBS) and multiple chip modules (MCMs) can be manufactured with buses formed on one or more layers thereof to provide the desired high-speed connections. Generally, a circuit element transmits a signal over the transmission line utilizing an output buffer to provide drive signals from the circuit element to the transmission line. Ideally, the output impedance of such output buffers is matched with a characteristic impedance of the transmission line. However, in reality, the output impedance of such output buffers is frequently mismatched with the characteristic impedance of the transmission line. The end result can be a significant decrease in signal integrity due to the mismatch, and a subsequent decrease in system performance.

The problem of signal degradation caused by a mismatch between buffers and buses becomes worse as the speed of the buses is increased. One reason for this is that, as the speed of the buses increases, electrical delay on the buses becomes long compared with the edge rate of the digital pulses, resulting in significant reflections on the bus. A recent example of a high-speed bus is the back side bus of the Pentium II (a registered trademark of INTEL Corporation) processor, which presently runs faster than 200 MHz. At such high bus speeds, it is necessary for the impedance match between the output impedances of the buffers and the characteristic impedance of the buses to be as close as possible. One solution to this problem is simply to test the characteristic impedance of the bus or buses formed on substrates of PCBs or MCMs using a Time-Domain Reflectometer (TDR). Unfortunately, this approach significantly increases the overall cost of the boards, which, of course, increases the overall product cost.

What is needed, therefore, is to provide a low-cost method and apparatus for testing characteristic impedance of transmission lines.

### SUMMARY

An exemplary apparatus for testing characteristic impedance of transmission lines includes a variable resistor, a first comparator, a second comparator, and a counter. One terminal of the variable resistor is coupled to a signal source, another terminal of the variable resistor is coupled to one terminal of a transmission line, and another terminal of the transmission line is idle. The one terminal of the transmission line is coupled to the input terminals of the first and second comparators respectively. The output terminals of the first and second comparators are respectively coupled to input terminals of the counter. An output terminal of the counter is coupled to an adjusting terminal of the variable resistor, the counter adjusts the resistance of the variable resistor according to signals output from the first and second comparators.

Other advantages and novel features of the present invention will become more apparent from the following detailed description of preferred embodiment when taken in conjunction with the accompanying drawings, in which:

### BRIEF DESCRIPTION OF THE DRAWINGS

FIG. 1 is a circuit diagram of an embodiment of an apparatus for testing characteristic impedance of transmission lines in accordance with the present invention; and

FIG. 2 is a flow chart of an embodiment of a method for testing characteristic impedance of transmission lines using the apparatus of FIG. 1.

### DETAILED DESCRIPTION

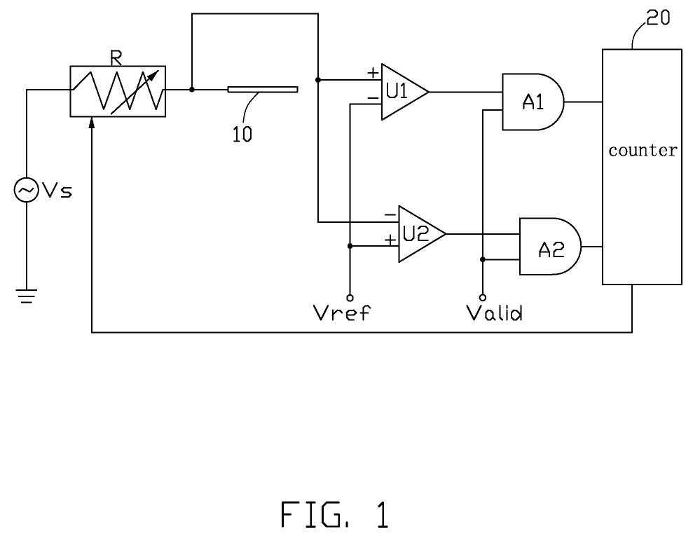

Referring to FIG. 1, an apparatus for testing characteristic impedance of a transmission line in accordance with an embodiment of the present invention includes a variable resistor R, a first comparator U1, a second comparator U2, a first AND gate A1, a second AND gate A2, and a counter 20. One terminal of the variable resistor R is coupled to a signal source Vs, the other terminal of the variable resistor R is coupled to one terminal of a transmission line 10, and the other terminal of the transmission line 10 is idle. The one terminal of the transmission line 10 is coupled to a non-inverting input terminal of the first comparator U1 and an inverting input terminal of the second comparator U2. An inverting input terminal of the first comparator U1 and a non-inverting input terminal of the second comparator U2 are coupled to a reference voltage Vref. The output terminals of the first and second comparators U1, U2 are respectively coupled to first input terminals of the first and second AND gates A1, A2. Second input terminals of the first and second AND gates A1, A2 are coupled to an enable signal Valid, and output terminals of the first and second AND gates A1, A2 are respectively coupled to two input terminals of the counter 20. An output terminal of the counter 20 is coupled to an adjusting terminal of the variable resistor R.

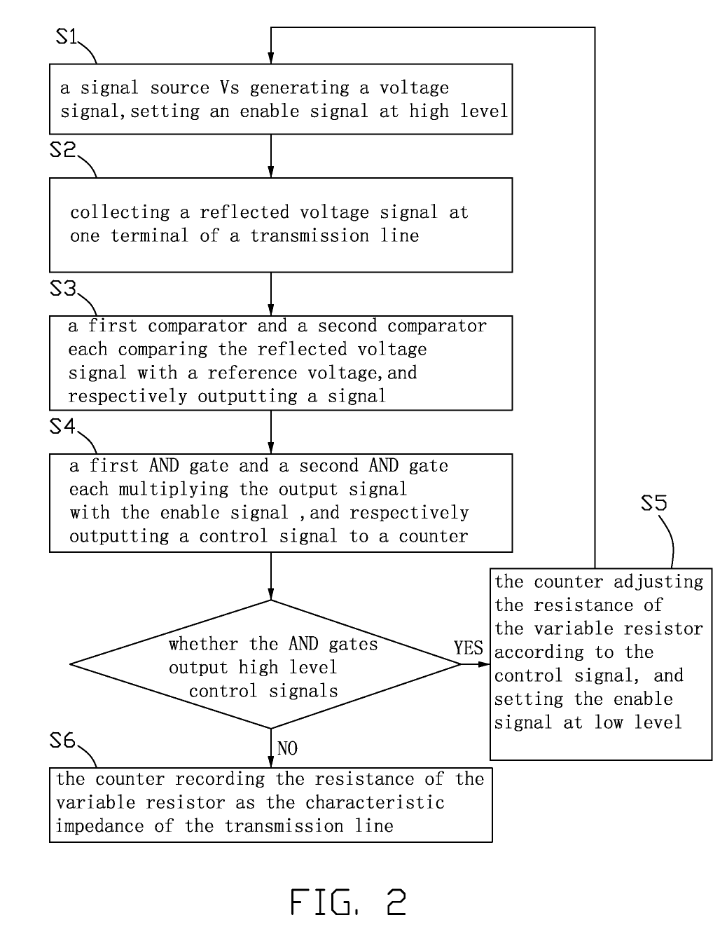

Referring to FIG. 2, a method for testing characteristic impedance of the transmission line 10 includes the following steps:

S1: the signal source Vs generating a voltage signal, the voltage signal is transmitted to the transmission line 10 via the variable resistor R, the voltage signal traveling in the transmission line and reflected back from the other terminal of the transmission line 10, setting the enable signal Valid at high level.
S2: collecting the reflected voltage signal V1 at the one terminal of the transmission line 10, the reflected voltage signal V1 is transmitted to the first and second comparators U1, U2.
S3: the first and second comparators U1, U2 each comparing the reflected voltage signal V1 with the reference voltage Vref, and outputting a signal to the first and second AND gates A1, A2 respectively; if the reflected voltage signal V1 is greater than the reference voltage Vref, the first comparator U1 outputs a high level signal, and the second comparator U2 outputs a low level signal; if the reflected voltage signal V1 is less than the reference voltage Vref, the first comparator U1 outputs a low level signal, and the second comparator U2 outputs a high level signal; if the reflected voltage signal V1 is equal to the reference voltage Vref, the first and second comparators U1, U2 both output low level signals.
S4: the first and second AND gates A1, A2 respectively multiplying the output signal with the enable signal Valid, and outputting a control signal to the counter 20 respectively; if the first comparator U1 outputs a high level signal, and the second comparator U2 outputs a low level signal, the first AND gate A1 outputs a high level control signal, and the second AND gate A2 outputs a low level control signal; if the first comparator U1 outputs a low level signal, and the second comparator U2 outputs a high level signal, the first AND gate A1 outputs a low level control signal, and the second AND gate A2 outputs a high level control signal; if the first and second comparators U1, U2 both output low level signals, the first and second AND gates A1, A2 both output low level control signals.

If the first and second AND gates A1, A2 both output low level control signals, executing step S6, the counter 20 recording the resistance of the variable resistor R as the characteristic impedance of the transmission line 10; if either of the first and second AND gates A1, A2 outputs a high level control signal, executing step S5, the counter 20 adjusting the resistance of the variable resistor R according to the control signal; if the first AND gate A1 outputs a high level control signal, the counter 20 increases the resistance of the variable resistor R, then sets the enable signal Valid at low level, and repeats the above steps until the first and second AND gates A1, A2 both output low level control signals; if the second AND gate A2 outputs a high level control signal, the counter 20 decreases the resistance of the variable resistor R, then sets the enable signal Valid at low level, and repeats the above steps until the first and second AND gates A1, A2 both output low level control signals. In this embodiment, the amplitude of the reference voltage Vref is half of that of the voltage signal.

In another embodiment, the first and second AND gates A1, A2 can be omitted, the output terminals of the first and second comparators U1, U2 are directly coupled to the two input terminals of the counter 20 respectively. The counter 20 records the characteristic impedance of the transmission line 10 or adjusts the resistance of the variable resistor R according to the output signals from the first and second comparators U1, U2. If the first and second comparators U1, U2 both output low level signals, the counter 20 records the resistance of the variable resistor R as the characteristic impedance of the transmission line 10; if the first comparator U1 outputs a high level signal, the counter 20 increases the resistance of the variable resistor R, then repeats the above steps until the first and second comparators U1, U2 both output low level signals; if the second comparator U2 outputs a high level signal, the counter 20 decreases the resistance of the variable resistor R, then repeats the above steps until the first and second comparators U1, U2 both output low level signals.

The testing method and apparatus do not use the expensive Time-Domain Reflectometer (TDR), but instead use low-cost items such as the variable resistor, comparators, AND gates and counter, so the costs of production can be decreased.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. An apparatus for testing characteristic impedance of a transmission line, comprising:
a variable resistor having one terminal coupled to a signal source to receive a voltage signal, and another terminal of the variable resistor coupled to one terminal of the transmission line, another terminal of the transmission line being idle;
a first comparator, the non-inverting input terminal of the first comparator coupled to said one terminal of the transmission line, the inverting input terminal of the first comparator coupled to a reference voltage;
a second comparator, the inverting input terminal of the second comparator coupled to said one terminal of the transmission line, the non-inverting input terminal of the second comparator coupled to the reference voltage; and
a counter having two input terminals respectively coupled to the output terminals of the first and the second comparators to receive an output signal therefrom, and an output terminal coupled to an adjusting terminal of the variable resistor, the counter adjusting the resistance of the variable resistor according to the output signal from the first and second comparators.

2. The apparatus as claimed in claim 1, further comprising a first AND gate and a second AND gate comprising first input terminals respectively coupled to the output terminals of the first and the second comparators, second input terminals receiving an enable signal, and output terminals respectively coupled to the two input terminals of the counter.

3. The apparatus as claimed in claim 2, wherein the first and the second AND gates are activated when the enable signal is at a high level.

4. The apparatus as claimed in claim 1, wherein the amplitude of the reference voltage is half of that of the voltage signal.

5. A method for testing characteristic impedance of a transmission line, comprising the following steps:
a signal source generating a voltage signal, the voltage signal transmitted to the transmission line via a variable resistor, the voltage signal traveling in the transmission line and reflected back from a remote terminal of the transmission line;
collecting the reflected signal between the variable resistor and the transmission line, then transmitting the reflected signal to a first comparator and a second comparator; and
the first and the second comparators each comparing the reflected signal with a reference voltage, and outputting a signal to a counter;
if the first and the second comparators both output low level signals, the counter records the resistance of the variable resistor as the characteristic impedance of the transmission line;
if either of the first and the second comparators outputs a high level signal, the counter adjusts the resistance of the variable resistor, and then repeats the above steps until the first and the second comparators both output low level signals.

6. The method as claimed in claim 5, further comprising a step of: the signals from the first and the second comparators are output to a first AND gate and a second AND gate respectively before being output to the counter, the first and the second AND gates each multiplying the output signal with an enable signal.

7. The method as claimed in claim 5, wherein the counter increases the resistance of the variable resistor if the first comparator outputs a high level signal.

8. The method as claimed in claim 5, wherein the counter decreases the resistance of the variable resistor if the second comparator outputs a high level signal.

9. The method as claimed in claim 5, wherein the amplitude of the reference voltage is half of that of the voltage signal.
